(19) United States
(12) Patent Application Publication
(10) Pub. No.: US 2017/0112023 A1
(43) Pub. Date: Apr. 20, 2017

(54) COOLING SYSTEM FOR DATA CENTER

(71) Applicant: HON HAI PRECISION INDUSTRY CO., LTD., New Taipei (TW)

(72) Inventors: TZE-CHERN MAO, New Taipei (TW); CHIH-HUNG CHANG, New Taipei (TW); YEN-CHUN FU, New Taipei (TW); YAO-TING CHANG, New Taipei (TW); CHAO-KE WEI, New Taipei (TW); HUNG-CHOU CHAN, New Taipei (TW)

(21) Appl. No.: 14/974,091

(22) Filed: Dec. 18, 2015

(30) Foreign Application Priority Data
Oct. 19, 2015 (CN) 201510674815.2

(51) Int. Cl. H05K 7/20

(52) U.S. Cl. CPC H05K 7/20554

(57) ABSTRACT

A cooling system for data center includes a server cabinet, a electronic equipment and a cooling module. The server cabinet includes a number of first check valves and second check valves. The cooling module includes a number of first cooling fans and heat-exchange equipments. The cooling system for data center can turn on or turn off the first cooling fans or the heat-exchange equipments to cool the electronic equipment if needed.

### CROSS-REFERENCE TO RELATED APPLICATIONS

This application claims priority to Chinese Patent Application No. 201510674815.2 filed on Oct. 19, 2015, the contents of which are incorporated by reference herein.

### FIELD

The subject matter herein generally relates to cooling systems, and more particularly to a cooling system for a data center.

### BACKGROUND

In order to allow electronics to function properly, data centers may need to adjust cooling based on ambient temperature. More and more data centers use cold air from outside to dissipate heat.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric, assembled view of a first embodiment of a cooling system for data center.

FIG. 2 is an isometric, exploded view of the cooling system for data center of FIG. 1.

FIG. 3 is similar to FIG. 2, but viewed from a different angle.

FIG. 4 is an isometric, assembled view of the first embodiment of the cooling system for data center showing a first air path.

FIG. 5 is an isometric, assembled view of the first embodiment of the cooling system for data center showing a second air path.

FIG. 6 is an isometric, assembled view of the first embodiment of the cooling system for data center showing a third air path.

FIG. 7 is an isometric, assembled view of a second embodiment of the cooling system for data center showing an air path.

FIG. 8 is an isometric, assembled view of a third embodiment of the cooling system for data center showing an air path.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The term “comprising” when utilized, means “including, but not necessarily limited to”; it specifically indicates open-ended inclusion or membership in the so-described combination, group, series and the like.

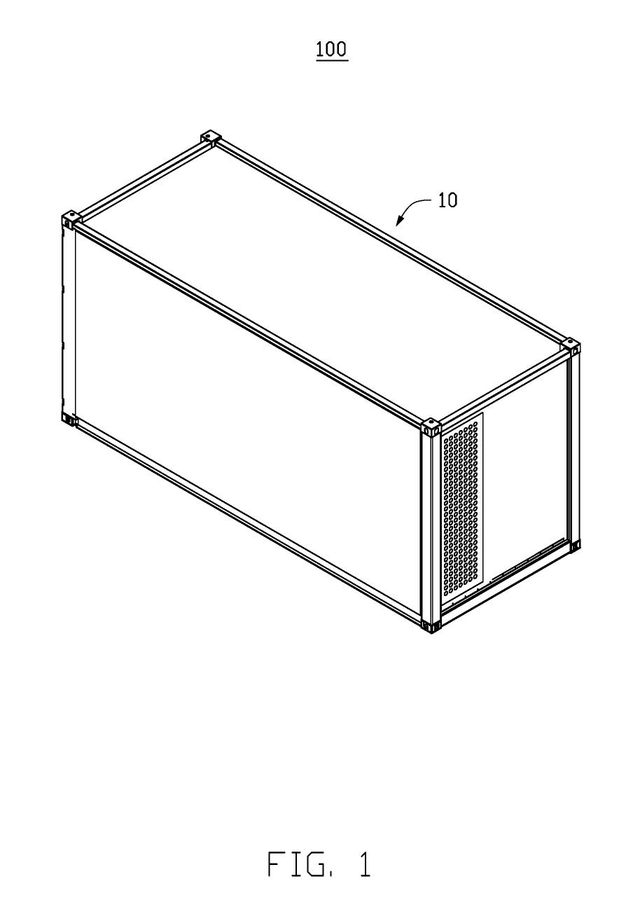

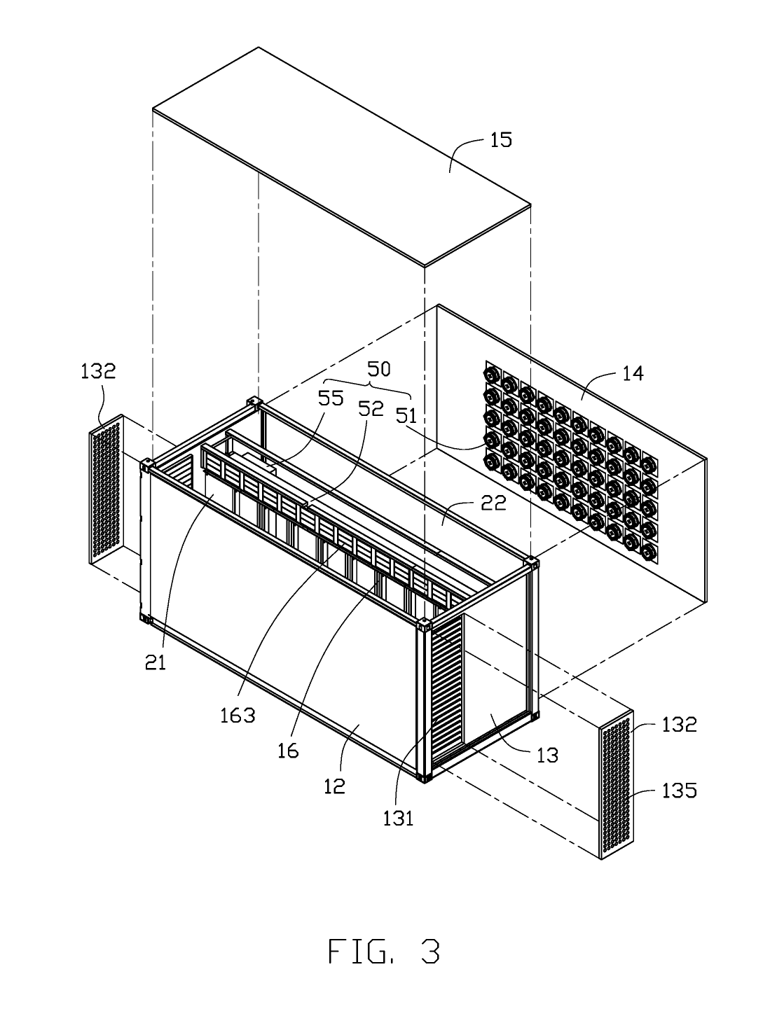

FIG. 1 illustrates a first embodiment of a cooling system 100 for a data center. The cooling system 100 includes a server cabinet 10 configured to receive a plurality of electronic equipment (not shown) and a cooling module 50 installed in the server cabinet 10 (shown in FIG. 3).

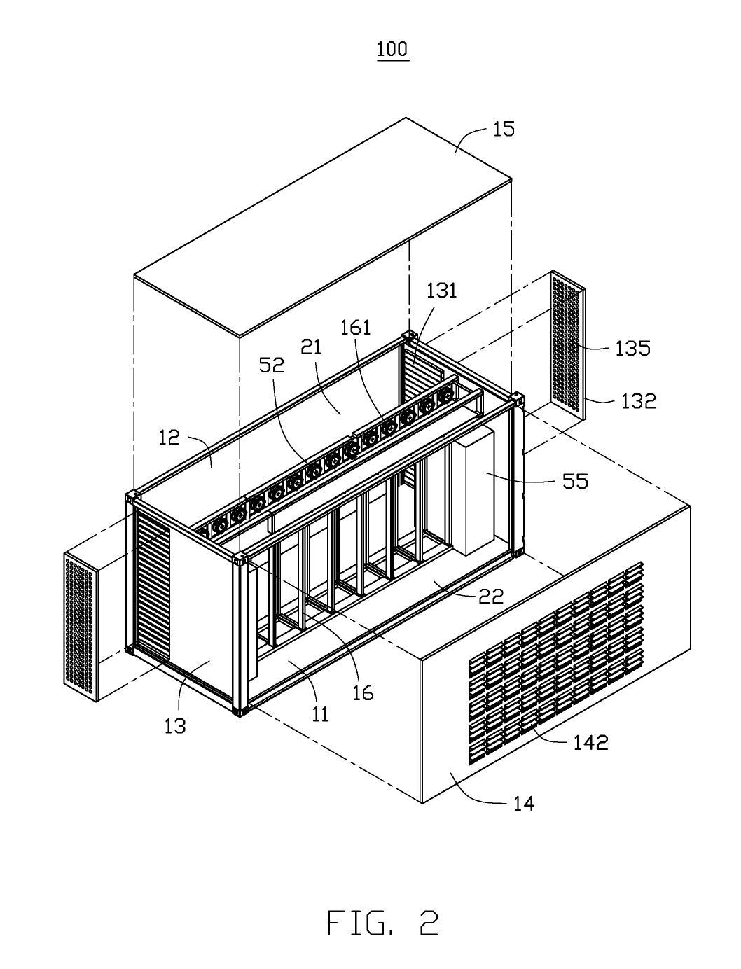

FIGS. 2 and 3 illustrate the server cabinet 10 includes a bottom wall 11, a front wall 12 perpendicularly connected on one side of the bottom wall 11, two sidewalls 13 perpendicularly connected on two opposite ends of the bottom wall 11, a rear wall 14 perpendicularly connected on the other side of the bottom wall 11 and a cover 15 parallel to the bottom wall 11. A rack 16 is located on the bottom wall 11; the rack 16 is configured to receive the electronic equipment. The bottom wall 11, the front wall 12, the two sidewalls 13, the cover 15, and the rack 16 cooperatively define a first receiving space 21. The bottom wall 11, the two sidewalls 13, the rear wall 14, the cover 15, and the rack 16 cooperatively define a second receiving space 22.

Each sidewall 13 is equipped with a first check valve 131, the air outside the server cabinet 10 can pass through the first check valve 131 to flow into the server cabinet 10, and the air inside the server cabinet 10 is blocked from flowing out of the server cabinet 10 by the first check valve 131. Each sidewall 13 is equipped with a filter plate 132 located above the first check valve 131. The filter plate 132 is configured to prevent dust from entering the server cabinet 10. A plurality of filter holes 135 are defined in the filter plate 132 to allow the air to pass through. The rear wall 14 is equipped with a plurality of second check valves 142. The second check valve 142 allows the air inside the server cabinet 10 to flow out from the server cabinet 10, and the second check valve 142 can block the air outside the server cabinet 10 from flowing into the server cabinet 10.

The rack 16 includes a bracket 161, the bracket 161 is equipped with a plurality of third check valves 163. The third check valves 163 are configured to allow air from the second receiving space 22 to pass through into the first receiving space 21, and the third check valves 163 prevent the air from the first receiving space 21 from flowing into the second receiving space 22.

The cooling module 50 includes a plurality of first cooling fans 51, a plurality of second cooling fans 52 and two heat-exchange equipments 55. The first cooling fans 51 are secured on the rear wall 14 and can drive the air flow to the second check valves 142. The second cooling fans 52 are received in the second receiving space 22. The second cooling fans 52 are secured on the bracket 161 and can drive the air flow to the third check valves 163. The two heat-exchange equipments 55 are respectively secured on the two ends of the rack 16 close to the side walls 13. The heat-exchange equipment 55 can drive the air flow of the second receiving space 22 to enter the first receiving space 21.

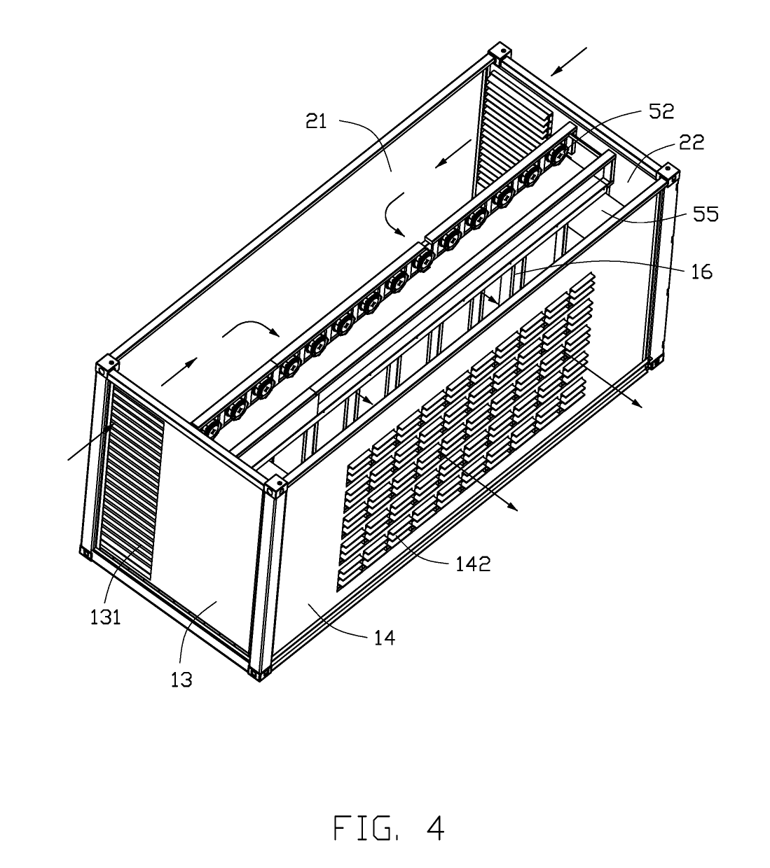

FIG. 4 illustrates when the predetermined environmental condition is suitable or reached (low temperature, low humidity, little dust, and so on) for air flow to cool the server cabinet 10. The first cooling fans 51 are turned on, the second cooling fans 52 and the heat-exchange equipments are turned off. The cold air flow outside the server cabinet 10 is configured to pass through the filter plates 132 and the first check valves 131 to flow into the first receiving space 21. Then the cold air flow passes between the electronic equipment of the rack 16, and absorbs the heat from the electronic equipment to become hot air flow, and then flows into the second receiving space 22. The first cooling fans 51 drive the hot air flow to pass through the second check valves 142 to flow out of the server cabinet 10 to cool the electronic equipment.

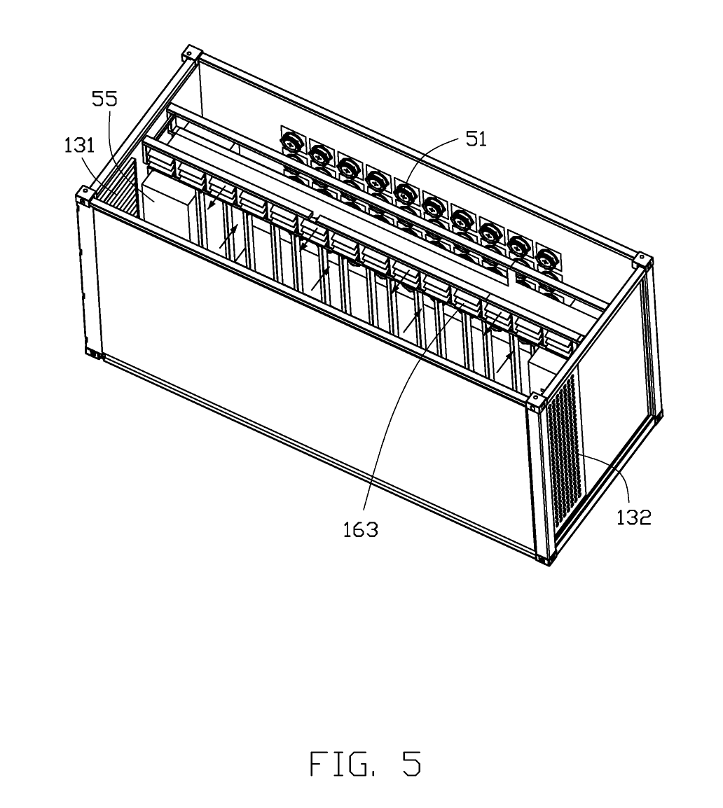

FIG. 5 illustrates when the temperature inside the server cabinet is low and does not require air flow to be input, the first cooling fans 51 and the heat-exchange equipments 55 are turned off, the second cooling fans 52 are turned on. The electronic equipment transfers the heat to the second receiving space 22. The hot air flow of the second receiving space 22 passes through the third check valves 163 to flow into the first receiving space 21 after absorb the heat of the electronic equipment. Then the hot air flow passes the gap between the electronic equipment to return to the second receiving space 22 to warm the sever cabinet 10, and the electronic equipment can be self-heating. When the temperature of the first receiving space 21 is higher than the temperature of the electronic equipment, the first cooling fans 51 are turned on. The cold air flow outside the server cabinet 10 is flowed into the sever cabinet 10 and is mixed with the hot air flow inside the sever cabinet 10 to let the temperature of the first receiving space 21 is suitable for electronic equipment working.

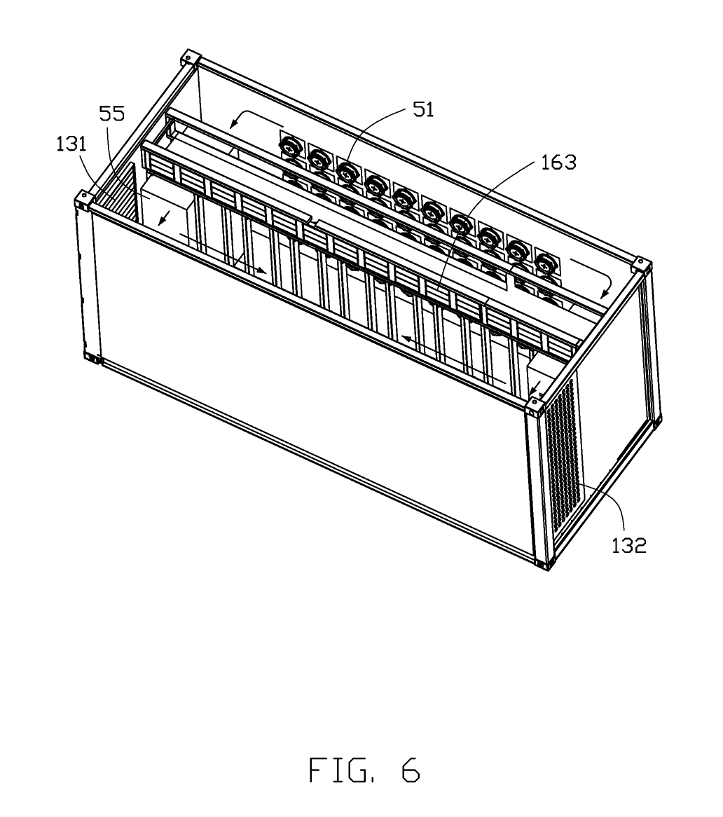

FIG. 6 illustrates when the temperature inside the server cabinet is high and needs to cool, the first cooling fans 51 and the second cooling fans 52 are turned off, the heat-exchange equipments 55 are turned on. The hot air flow, of the second receiving space 22 driven by the heat-exchange equipment 55, flows into the heat-exchange equipment 55. The heat of the hot air flow is transferred to the heat-exchange equipment 55 and the hot air flow flows into the first receiving space 21 to cool to become cold air flow. The cold air flow passes between the electronic equipment of the rack 16 to cool the electronic equipment by absorbing the heat of the electronic equipment to become hot air flow, and then the air flow returns to the second receiving space 22.

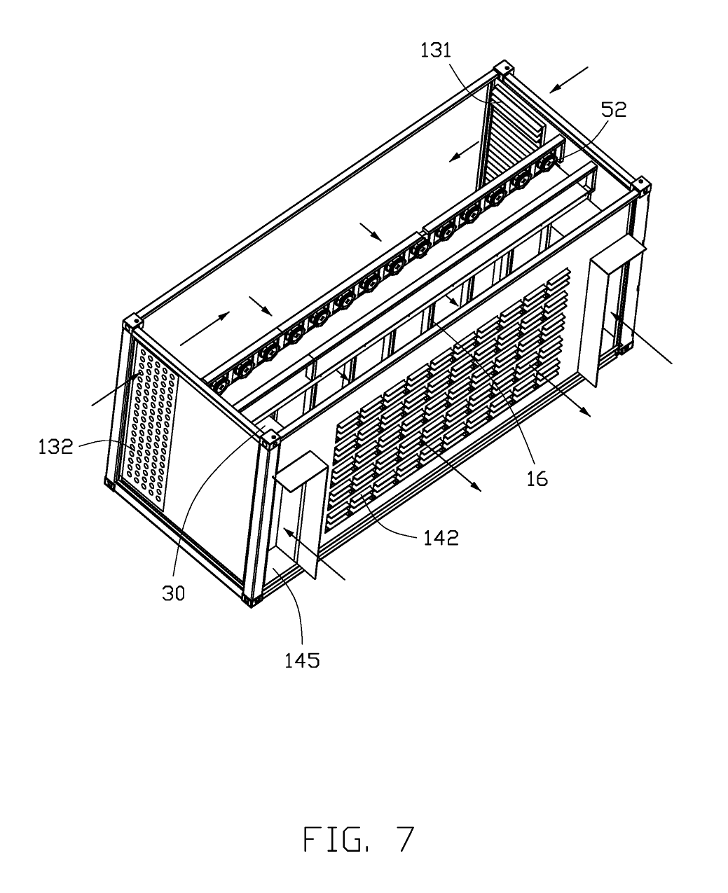

FIG. 7 illustrates a second embodiment of the cooling system 100. An air vent 145 is defined in each end of the rear wall 14. An air duct 30 is located between the heat-exchange equipment 55 and the air vent 145.

When the predetermined environmental condition is suitable or reached (low temperature, low humidity, little dust, and so on) for air flow to cool the server cabinet 10, the first cooling fans 51 and the heat-exchange equipments 55 are turned on, the second cooling fans 52 are turned off. The cold air flow outside the server cabinet 10 passes the first check valves 131 and the air vents 145 to flow into the first receiving space 21. Then the cold air flow passes between the electronic equipment of the rack 16, and absorbs the heat of the electronic equipment to become hot air flow, and then flows into the second receiving space 22. The first cooling fans 51 drive the hot air flow through the second check valves 142 to go out of the server cabinet 10 to cool the electronic equipment quickly.

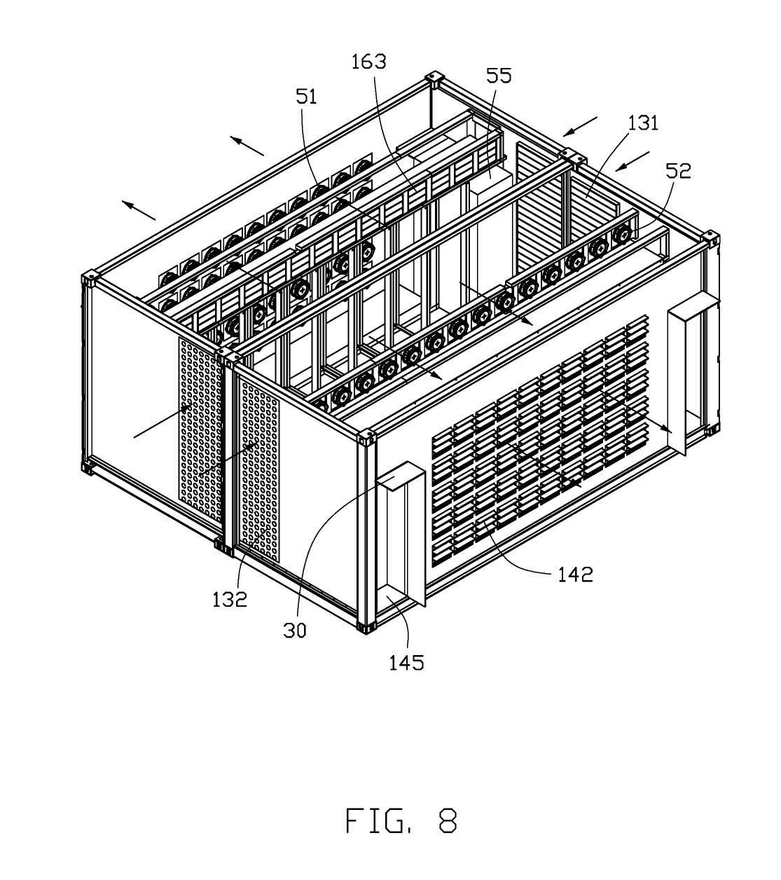

FIG. 8 illustrates a third embodiment of the cooling system 100. Two cooling systems 100 are secured together. The two front walls 12 are removed and the two first receiving spaces 21 are connected together.

When the server cabinet 10 needs to be cooled, the first cooling fans 51 and the heat-exchange equipments 55 are turned on, the second cooling fans 52 are turned off. The cold air flow from outside the server cabinet 10 passes through the first check valves 131 and the air vents 145 to flow into the first receiving space 21. Then the cold air flow passes between the electronic equipment of the rack 16, and absorbs the heat of the electronic equipment to become hot air flow, and flows into the second receiving space 22. The first cooling fans 51 drive the hot air flow through the second check valves 142 out of the server cabinet 10 to cool the electronic equipment quickly.

The embodiments shown and described above are only examples. Many details are often found in the art such as the other features of a cooling system for data center. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A cooling system for data center, comprising:
a server cabinet comprising:
a plurality of first check valves; and
a plurality of second check valves;
a plurality of electronic equipments installed on the server cabinet; and
a cooling module comprising:
a plurality of first cooling fan; and
a plurality of heat-exchange equipments;
wherein when a predetermined environmental condition is reached for air flow to cool the server cabinet, the first cooling fans are turned on, the heat-exchange equipments are turned off, the cold air flow outside the server cabinet is configured to pass through the first check valves and absorb the heat of the electronic equipment to become hot air flow, the first cooling fans drive the hot air flow passing through the second check valves to flow out of the server cabinet; and
wherein a predetermined environmental condition is not reached, the first cooling fans are turned off and the heat-exchange equipments are turned on, the cold air flow inside the server cabinet is configured to pass through the electronic equipments and absorb the heat of the electronic equipments to become hot air flow to flow into the heat-exchange equipments, the heat of the hot air flow is transferred to the heat-exchange equipment to become cold air flow, and returned to pass through the electronic equipment.

2. The cooling system of claim 1, wherein the server cabinet further comprises a plurality of third check valves, and the cooling module further comprises a plurality of second cooling fans, when the temperature inside the server cabinet is low and the environment is not suitable, the first cooling fans and the heat-exchange equipments are turned off, the second cooling fans are turned on, the second cooling fans drive the air flow passing through the third check valves, the air flow is returned to the second cooling fans after passing through the electronic equipments.

3. The cooling system of claim 2, wherein the server cabinet comprises a bottom wall, a front wall perpendicularly connected on one side of the bottom wall, two sidewalls perpendicularly connected on two ends of the bottom wall, a rear wall perpendicularly connected on the other side of the bottom wall and a cover parallel to the bottom wall, the first check vales are located on the two sidewalls, the air flow outside the server cabinet can pass through the first check valve to flow into the server cabinet, and the air flow inside the server cabinet is prevent from flowing out of the server cabinet by blocking via the first check valve.

4. The cooling system of claim 2, wherein each sidewall is equipped with a filter plate located above the first check valve, the filter plate is configured to prevent the dust flowing into the server cabinet, the filter plate is defined a plurality of filter holes configured to allow the air flow passing through.

5. The cooling system of claim 4, wherein the second check valves are located on the rear wall, the air flow inside the server cabinet can pass through the second check valve to flow out of the server cabinet, and the air flow outside the server cabinet is prevent from flowing into the server cabinet by blocking via the second check valve.

6. The cooling system of claim 5, wherein the first cooling fans are located on the rear wall, and the first cooling fans are configured to drive the air flow to the second check valves.

7. The cooling system of claim 1, wherein a rack is located on the bottom wall, the electronic equipments are received in the rack, the bottom wall, the front wall, the two sidewalls, the cover and the rack cooperatively define a first receiving space, the bottom wall, the two sidewalls, the rear wall, the cover and the rack cooperatively define a second receiving space.

8. The cooling system of claim 7, wherein the rack comprises a bracket, the third check valves are located on the bracket, the air flow of the second receiving space can pass through the third check valves to flow into the first receiving space, and the air flow of the first receiving space is prevent from flowing into the second receiving space by blocking via the third check valves.

9. The cooling system of claim 8, wherein the second cooling fans are located on the bracket, the second cooling fans are configured to drive the air flow to the third check valves, and the heat-exchange equipments are respectively secured on the two ends of the rack and close to the side walls.

10. The cooling system of claim 8, wherein each end of the rear wall is defined an air vent, an air duct is located between the heat-exchange equipment and the air vent.

11. A cooling system for a data center, comprising:
a server cabinet comprising:
a plurality of first check valves; and
a plurality of second check valves;
a plurality of electronic equipments secured in the server cabinet; and
a cooling module comprising:
a plurality of first cooling fan; and
a plurality of heat-exchange equipments;
wherein the first cooling fans are configured to drive the air flow from the first check valves to the second check valves, and the heat-exchange equipments are configured to absorb the heat of the air flow inside the server cabinet; and
wherein the cooling system for data center can turn on or turn off the first cooling fans or the heat-exchange equipments to cool the electronic equipments according to whether the environment is suitable for inputting air flow to cool the server cabinet.

12. The cooling system of claim 11, wherein the server cabinet further comprises a plurality of third check valves, and the cooling module further comprises a plurality of second cooling fans, when the temperature inside the server cabinet is low and the environment is not suitable, the first cooling fans and the heat-exchange equipments are turned off, the second cooling fans are turned on, the second cooling fans drive the air flow passing through the third check valves, the air flow is returned to the second cooling fans after passing through the electronic equipments.

13. The cooling system of claim 12, wherein the server cabinet comprises a bottom wall, a front wall perpendicularly connected on one side of the bottom wall, two sidewalls perpendicularly connected on two ends of the bottom wall, a rear wall perpendicularly connected on the other side of the bottom wall and a cover parallel to the bottom wall, the first check vales are located on the two sidewalls, the air flow outside the server cabinet can pass through the first check valve to flow into the server cabinet, and the air flow inside the server cabinet is prevent from flowing out of the server cabinet by blocking via the first check valve.

14. The cooling system of claim 12, wherein each sidewall is equipped with a filter plate located above the first check valve, the filter plate is configured to prevent the dust flowing into the server cabinet, the filter plate is defined a plurality of filter holes configured to allow the air flow passing through.

15. The cooling system of claim 14, wherein the second check valves are located on the rear wall, the air flow inside the server cabinet can pass through the second check valve to flow out of the server cabinet, and the air flow outside the server cabinet is prevent from flowing into the server cabinet by blocking via the second check valve.

16. The cooling system of claim 15, wherein the first cooling fans are located on the rear wall, and the first cooling fans are configured to drive the air flow to the second check valves.

17. The cooling system of claim 11, wherein a rack is located on the bottom wall, the electronic equipments are received in the rack, the bottom wall, the front wall, the two sidewalls, the cover and the rack cooperatively define a first receiving space, the bottom wall, the two sidewalls, the rear wall, the cover and the rack cooperatively define a second receiving space.

18. The cooling system of claim 17, wherein the rack comprises a bracket, the third check valves are located on the bracket, the air flow of the second receiving space can pass through the third check valves to flow into the first receiving space, and the air flow of the first receiving space is prevent from flowing into the second receiving space by blocking via the third check valves.

19. The cooling system of claim 18, wherein the second cooling fans are located on the bracket, the second cooling fans are configured to drive the air flow to the third check valves, and the heat-exchange equipments are respectively secured on the two ends of the rack and close to the side walls.

20. The cooling system of claim 18, wherein each end of the rear wall is defined an air vent, an air duct is located between the heat-exchange equipment and the air vent.
